(19) United States
(12) Patent Application Publication
(10) Pub. No.: US 2026/0132511 A1
(43) Pub. Date: May 14, 2026

(54) SYSTEMS AND METHODS FOR MONITORING PROCESSING APPARATUS

(71) Applicant: ASM IP Holding B.V., Almere (NL)

(72) Inventors: Hannelore Azora Hemminger, Tempe, AZ (US); Eric James Shero, Phoenix, AZ (US); Todd Robert Dunn, Cave Creek, AZ (US)

(21) Appl. No.: 19/383,895

(22) Filed: Nov. 10, 2025

Related U.S. Application Data
(60) Provisional application No. 63/720,052, filed on Nov. 13, 2024.

(51) Int. Cl. C23C 16/458; C23C 16/46; C23C 16/52; G01J 5/0821

(52) U.S. Cl. CPC C23C 16/458; C23C 16/46; C23C 16/52; G01J 5/0821

(57) ABSTRACT

A reactor system can comprise a substrate carrier, which can be configured to move a substrate within the reactor system, and/or a translating arm; a temperature measurement device; a processor; and/or a tangible, non-transitory memory configured to communicate with the processor having instructions stored thereon that, in response to execution by the processor, cause the processor to perform operations. The temperature measurement device can be coupled to the substrate carrier and/or translating arm, and/or the temperature measurement device can be coupled another component of the reactor system. The temperature measurement device can be configured to measure a temperature of a processed substrate within the reaction system. The processor can perform operations including measuring the temperature of the substrate; and/or comparing the measured temperature with a reference temperature.

### CROSS-REFERENCE TO RELATED APPLICATIONS

This application is a nonprovisional of, and claims priority to and the benefit of, U.S. Provisional Patent Application No. 63/720,052, filed Nov. 13, 2024 and entitled “SYSTEMS AND METHODS FOR MONITORING PROCESSING APPARATUS,” which is hereby incorporated by reference herein.

### FIELD

The present disclosure relates generally to a semiconductor processing apparatus and monitoring and controlling the same.

### BACKGROUND

Reaction chambers may be used for depositing material layers onto various substrates, such as semiconductor substrates. A semiconductor substrate, such as, for example, a silicon substrate, may be placed on a substrate support structure (e.g., a susceptor) inside a reaction chamber. Both the substrate and the substrate support structure may be heated to a desired substrate temperature set point. In an example substrate treatment process, one or more reactant gases may be passed over a heated substrate, causing the deposition of a thin film of material on the substrate surface.

Various process parameters may be carefully controlled during processing to achieve the high quality and desired specifications of the deposited layers. An example of one such process parameter is the substrate temperature. For example, during an atomic layer deposition (ALD) process, the precursor gases may interact with the substrate within a particular temperature range for deposition on the substrate. As another example, during a chemical vapor deposition (CVD) process, the precursor gases may react and/or decompose within a particular temperature range to deposit on the substrate. A change in the temperature may result in a change in the resulting deposition, resulting in deposited layers with unideal and/or undesired characteristics. Accordingly, it is important to accurately monitor and/or control the substrate temperature and detect any system malfunctions or other problems before they are propagated to other steps in a deposition or manufacturing process and/or produce further problematic substrates or films.

Any discussion of problems and solutions in this section has been provided solely for the purposes of conveying a context for the present disclosure; such discussion should not be taken as an admission that any or all of the discussion was known at the time the disclosure was made.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a reactor system comprising a plurality of substrate supports; a substrate carrier comprising a plurality of substrate support arms, wherein the substrate carrier is configured to rotate about an axis such that each of the plurality of substrate support arms is able to align with each of the plurality of substrate supports, and wherein the substrate carrier is configured to move substrates between the plurality of substrate supports; and/or a temperature measurement device coupled to at least one of the plurality of substrate support arms. The temperature measurement device can be configured to measure a temperature of a measured portion of a processed substrate and travels with at least one of the plurality of substrate support arms during rotation along a travel path. The measured portion of the processed substrate, disposed on one of the plurality of substrate supports, can overlap the travel path. Each of the plurality of substrate support arms can comprise an end effector configured to engage a respective substrate. The temperature measurement device can be coupled to the end effector of each of the plurality of substrate support arms. The temperature measurement device can be at least one of a pyrometer or infrared camera.

The end effector can comprise an angled body at least partially defining an end effector void of the end effector, such that in response to a respective substrate being disposed on the end effector, the angled body engages with a peripheral portion of the respective substrate and the end effector void is aligned with at least a portion of a center portion of the respective substrate. The temperature measurement device can be positioned in or aligned with the end effector void.

The reactor system can further comprise a processor operably coupled to the temperature measurement device; and a tangible, non-transitory memory configured to communicate with the processor, the tangible, non-transitory memory having instructions stored thereon that, in response to execution by the processor, cause the processor to perform operations comprising: measuring, by the processor and the temperature measurement device, and as the substrate carrier rotates, the temperature along the measured portion of processed substrate that overlaps the travel path of the temperature measurement device; and/or comparing, by the processor, the measured temperature with a reference temperature. The operations can further comprise determining, by the processor, a difference between the measured temperature and the reference temperature; and/or comparing, by the processor, the difference to a threshold value.

In various examples, a reactor system can comprise a reaction chamber comprising a wall system defining a reaction space; a substrate support disposed in the reaction chamber and configured to receive a substrate thereon; a translating arm coupled to the wall system in the reaction chamber, wherein the translating arm can be configured to move within the reaction space, and at least a portion of the translating arm can be configured to travel above or below a substrate disposed on the substrate support; and/or a temperature measurement device coupled to the translating arm. The temperature measurement device can be at least one of a pyrometer or infrared camera. The temperature measurement device can be a pyrometer comprising a pyrometer body and a fiber optic. The pyrometer body can be disposed external to the reaction chamber and the fiber optic can be coupled to the translating arm within the reaction chamber. The temperature measurement device can be configured to move with the translating arm and travel above or below the substrate along a travel path and measure a temperature of a measured portion of the substrate overlapping the travel path. The translating arm can be coupled to a sidewall of the wall system. The translating arm can rotate via a hinge between a retracted position and an extended position. The travel path can be curved. The sidewall can comprise a recess in which the hinge can be at least partially disposed and in which the translating arm can be at least partially housed when in the retracted position. The reaction chamber can comprise an upper chamber and a lower chamber. The recess in the sidewall can be comprised in the lower chamber. The reactor system can further comprise a mirror coupled to the translating arm, wherein the mirror can be angled to direct an optical path from the fiber optic toward the substrate.

The reactor system can further comprise a processor operably coupled to the temperature measurement device; and/or a tangible, non-transitory memory configured to communicate with the processor, the tangible, non-transitory memory having instructions stored thereon that, in response to execution by the processor, cause the processor to perform operations comprising: measuring, by the processor and the temperature measurement device, and as the translating arm moves, the temperature along the measured portion of the substrate; and/or comparing, by the processor, the measured temperature with a reference temperature. The operations can further comprise determining, by the processor, a difference between the measured temperature and the reference temperature; and/or comparing, by the processor, the difference to a threshold value.

In various examples, a reactor system can comprise a first chamber; a load lock chamber coupled to the first chamber, wherein a substrate can travel through the load lock chamber along a transfer path in moving to and from the first chamber; a first pyrometer comprising a first pyrometer body and a first fiber optic, wherein the first pyrometer body can be disposed external to the load lock chamber and the first fiber optic can be disposed through an upper wall of, and into, the load lock chamber, wherein a first optical path of the first pyrometer can intersect the transfer path of the substrate; a processor operably coupled to the first pyrometer; and/or a tangible, non-transitory memory configured to communicate with the processor, the tangible, non-transitory memory having instructions stored thereon that, in response to execution by the processor, cause the processor to perform operations. The operations can comprise measuring, by the processor and the first pyrometer, and as the substrate moves along the transfer path, a first temperature along a first measured portion of the substrate that intersects the first optical path of the first pyrometer; and/or comparing, by the processor, the first temperature with a reference temperature. The operations can further comprise determining, by the processor, a difference between the first temperature and the reference temperature; and/or comparing, by the processor, the difference to a threshold value. The reactor system can further comprise a second pyrometer comprising a second pyrometer body and a second fiber optic. The second pyrometer body can be disposed external to the load lock chamber and the second fiber optic can be disposed through the upper wall of, and into, the load lock chamber. A second optical path of the second pyrometer can be parallel to the first optical path of the first pyrometer and can intersect the transfer path of the substrate. The operations can further comprise measuring, by the processor and the second pyrometer, and as the substrate can move along the transfer path, a second temperature along a second measured portion of the substrate that intersects the second optical path of the second pyrometer, wherein the first temperature and the second temperature can be comprised in a temperature profile; comparing, by the processor, the temperature profile with a reference temperature profile; determining, by the processor, a difference between the temperature profile and the reference temperature profile; and/or comparing, by the processor, the difference to a threshold profile value.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the disclosure may be embodied or carried out in a manner that achieves or optimizes one advantage or group of advantages as taught or suggested herein without necessarily achieving other objects or advantages as may be taught or suggested herein.

All of these examples are intended to be within the scope of the disclosure herein disclosed. These and other examples will become readily apparent to those skilled in the art from the following detailed description of certain examples having reference to the attached figures, the disclosure not being limited to any particular embodiment(s) disclosed.

### BRIEF DESCRIPTION OF THE DRAWINGS

While the specification concludes with claims particularly pointing out and distinctly claiming what are regarded as examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1 depicts a schematic diagram of a reactor system, in accordance with various examples.

FIG. 2 depicts a schematic diagram of a reactor system having multiple reaction chambers, in accordance with various examples.

FIG. 3 depicts a cross-sectional schematic diagram of a portion of an exemplary reactor system, in accordance with various examples.

FIGS. 4A and 4B depict a schematic diagram of an exemplary reaction chamber, in accordance with various examples.

FIG. 5 depicts a perspective view of an exemplary reaction chamber, in accordance with various examples.

FIG. 6A-6C depicts an exemplary reactor system having a multi-arm substrate carrier, in accordance with various examples.

FIG. 7 depicts another exemplary reactor system having a multi-arm substrate carrier, in accordance with various examples.

FIG. 8 depicts a method for detecting a change in a reactor system, in accordance with various examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. Unless otherwise noted, the exemplary embodiments or components thereof may be combined or may be applied separate from each other. Methods may include the disclosed steps in any suitable and/or desired order or combination.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the plural forms as well, unless the context indicates otherwise. It will be further understood that the terms “includes,” “comprises,” “including,” and/or “comprising” used herein specify the presence of stated features, integers, steps, processes, members, components, and/or groups thereof, but do not preclude the presence or addition of one or more other features, integers, steps, processes, members, components, and/or groups thereof.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes. Cyclic deposition processes can include plasma-enhanced steps. A cyclic deposition process can include one or more cycles that include plasma activation of a precursor, a reactant, and/or an inert gas in any combination.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

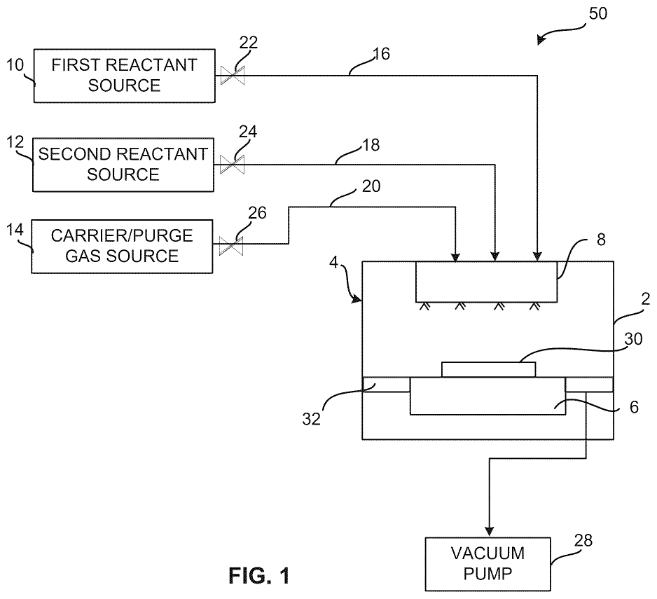

Reactor systems used for ALD, CVD, and/or the like, may be used for a variety of applications, including depositing and etching materials on a substrate surface. In various examples, with reference to FIG. 1, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and valves or controllers 22-26. Susceptor 6 and/or substrate 30 can be heated to a desired temperature for processing. Reactant gases or other materials from reactant sources 10, 12 can be applied to substrate 30 in reaction chamber 4. A purge gas from purge gas source 14 can be flowed to and through reaction chamber 4 to remove any excess reactant or other undesired materials from reaction chamber 4. System 50 can also comprise a vacuum source 28 fluidly coupled to the reaction chamber 4, which can be configured to evacuate reactants, a purge gas, or other materials out of reaction chamber 4.

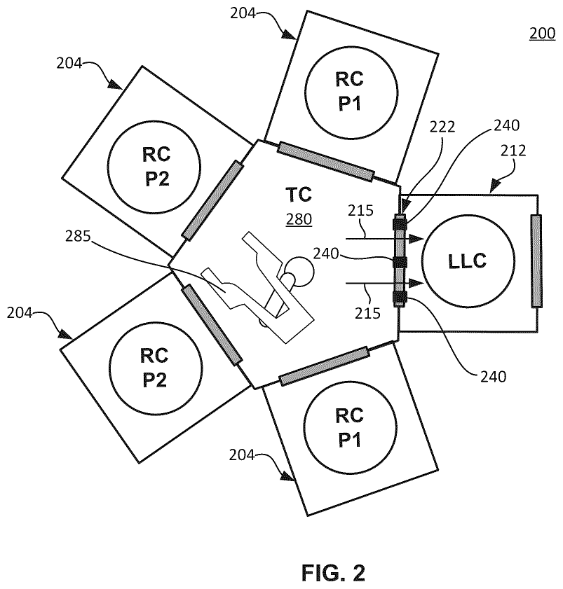

In various examples, a reactor system can comprise multiple reaction chambers. For example, in reactor system 200, shown in FIG. 2, a number of reaction chambers 204 (each of which can be an example of reaction chamber 4 in FIG. 1) can be disposed around and/or coupled to a transfer chamber 280 comprising a transfer tool 285 for transferring substrates between chambers within reaction system 200. Substrates can be transferred from a load lock chamber 212 and between reaction chambers 204 (e.g., through transfer chamber 280). For example, a substrate can be disposed in different chambers for different steps in a deposition process.

In various examples, substrates being transferred between chambers in a reactor system (e.g., reactor system 200) can travel through gate valves. For example, after processing in a reaction chamber 204 a substrate can travel from the respective reaction chamber 204 to transfer chamber 280, and from transfer chamber 280 through gate valve 222 to load lock chamber 212.

A reactor system can comprise one or more temperature measurement devices along a pathway of a substrate being transferred between chambers in a reactor system (e.g., coupled to or disposed on or in a pathway structure between chambers in a reactor system (e.g., a tunnel structure or the like)). The temperature measurement device can be any suitable device configured to measure temperature (e.g., a pyrometer, thermal imaging device, and/or the like). As known in the art, a pyrometer is a type of non-contact (i.e., remote) temperature sensor that may be utilized to determine the temperature of a target surface, such as the surface of a semiconductor substrate. A pyrometer may include an optical system that focuses the radiation of a target surface along an optical path into the detection system of the pyrometer. In some embodiments of the disclosure, an optical path of the pyrometer may intersect a transfer path (e.g., transfer path 215) of a substrate (e.g., a path the substrate travels between chambers in a reactor system, such as between load lock chamber 212 and transfer chamber 280, and/or between a reaction chamber 204 and transfer chamber 280).

For example, load lock chamber 212 can comprise one or more temperature measurement devices 240 (e.g., a pyrometer, thermal imaging device such as an infrared camera, and/or the like). In various examples, there can be one temperature measurement device 240 coupled to load lock chamber 212 configured to measure a temperature of a substrate traveling along transfer path 215 between transfer chamber 280 and load lock chamber 212. The temperature measurement device 240 can be disposed in any suitable position (e.g., along a center line of the travel path of the substrate, such that a center axis of the substrate is measured for temperature). In various examples, there can be multiple temperature measurement devices 240 coupled to load lock chamber 212, such that multiple axes along the substrate are measured for temperature, (e.g., along a center axis and a side axis, along axes equidistant from a center axis, and/or the like). Temperature measurement devices 240 can be coupled to gate valve 222 of load lock chamber 212, or any other suitable position. In various examples, temperature measurement devices can be coupled to one or more reaction chambers 204 or gate valves connecting a respective reaction chamber to transfer chamber 280.

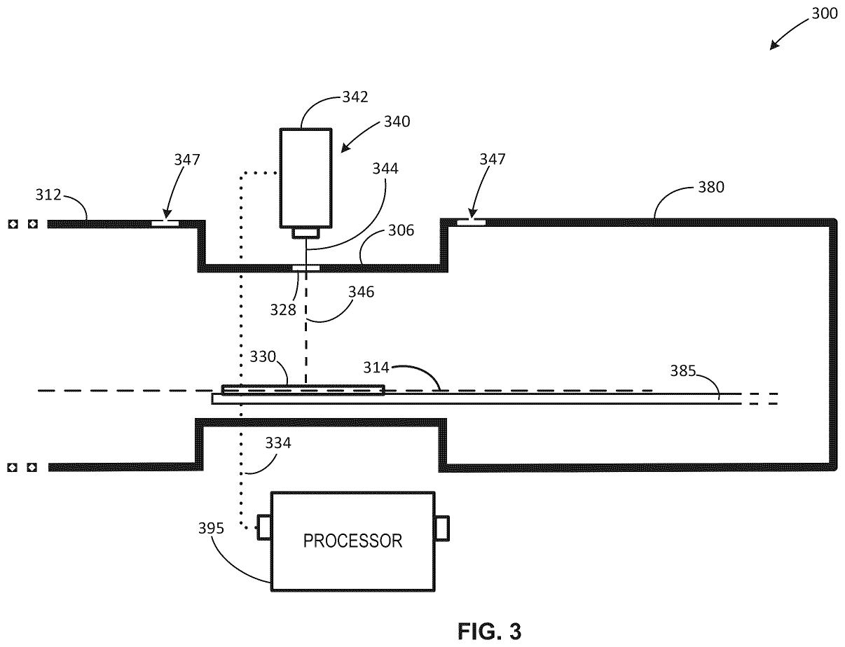

As shown in FIG. 3, reactor system 300 (e.g., depicting a portion of an example of reactor system 200 in FIG. 2) can include a load lock chamber 312 (an example of load lock chamber 212 in FIG. 2), a transfer chamber 380 (e.g., an example of transfer chamber 280 in FIG. 2), a transfer structure 306 disposed between transfer chamber 380 and load lock chamber 312 (e.g., gate valve 222 in FIG. 2), and/or a temperature measurement device 340 (an example of temperature measurement device 240 in FIG. 2). Transfer structure 306 can be part of load lock chamber 312. A substrate in reactor system 300 can travel along a transfer path 314 between chambers (an example of transfer path 215 in FIG. 2). Substrate 330 can be transferred between chambers via transfer tool 385 (an example of transfer tool 285 in FIG. 2).

In various examples, the temperature measurement device 340 can be coupled to transfer structure 306 and/or load lock chamber 312, or another other suitable portion of a reactor system). Temperature measurement device 340 comprising a pyrometer can comprise a pyrometer body 342 and a fiber optic 344. In various examples, a pyrometer that does not comprise a fiber optic can have the pyrometer body coupled to a component of reactor system. In various examples, pyrometer body 342 can be disposed external to components of reactor system 300, e.g., external to load lock chamber 312 and/or transfer structure 306. Fiber optic 344 can be coupled to load lock chamber 312 and/or transfer structure 306. With an arrangement including the pyrometer body being disposed external to a reactor system component(s) and the fiber optic being coupled thereto, there is more flexibility of implementing a pyrometer into a reactor system. That is, limited size or space in a reactor system may still be able to accommodate coupling and/or implementation of a fiber optic of a pyrometer rather than direct coupling of a pyrometer body.

Temperature measurement device 340 can comprise an optical path 346, wherein optical path 346 intersects the transfer path 314 between load lock chamber 312 and transfer chamber 380. Optical path 346 can be provided via fiber optic 344. Temperature measurement device 340, or a portion thereof (e.g., fiber optic 344) can be disposed in or through the upper wall (or any other suitable wall of a wall system) of reactor system 300 such that optical path 346 of temperature measurement device 340 intersects transfer path 314. At least a portion of temperature measurement device 340 can be positioned such that it is able to remotely measure the temperature of substrate 330 as substrate 330 is transferred between chambers, or otherwise transferred within reactor system 300. The portion of substrate 330 intersected by optical path 346, and therefore measured for temperature, can be referred to as the measured portion of substrate 330. Temperature measurement device 340, or fiber optic 344 thereof, can be disposed in the upper wall of transfer structure 306 at a fixed location, i.e., such that the optical path of temperature measurement device 340 is also fixed in space.

To enable the thermal radiation from a substrate to propagate along optical path 346 and to reach the detection systems of temperature measurement device 340, the ceiling or wall system (e.g., an upper wall) of transfer structure 306 and/or load lock chamber 312, to which temperature measurement device 340 is coupled, may comprise one or more apertures 347 through which temperature measurement device 340 (or its fiber optic 344) can be disposed, and/or windows, through which the thermal radiation from the substrate(s) may be transmitted and received/detected by temperature measurement device 340. As depicted in FIG. 3, temperature measurement device 340 is aligned with a window 328 disposed in the ceiling of transfer structure 306. For example, window 328 can be transparent and can be fabricated from quartz glass (i.e., window 328 can comprise quartz). As another example, window 328 can be opaque (e.g., not optically transparent), but can be transparent to infrared (IR) light or radiation (i.e., an IR-transparent window). Such a window 328 can comprise germanium.

In various examples, temperature measurement device 340 can be disposed at any suitable location along first transfer path 314 and/or in any suitable location in a reactor system. FIG. 3 depicts temperature measurement device 340 being disposed in transfer structure 306 between transfer chamber 380 and load lock chamber 312. But, the components discussed in relation to FIG. 3 can also be implemented in a transfer structure between two other chambers in a reactor system, such as on gate valve 222 between transfer chamber 280 and load lock chamber 212 depicted in FIG. 2. Further, additional pyrometers can be disposed along the respective transfer path of a substrate, such that the optical paths of the additional pyrometers intercept the substrate along the transfer path at different portions (e.g., axes) along the substrate. Any suitable number of pyrometers can be positioned to intersect the transfer path of a substrate, e.g., multiple pyrometers such that multiple temperature line scans can be measured across the substrate (e.g., simultaneously, and/or during the same substrate transfer event). For example, a first pyrometer can be disposed to intersect a center axis of substrate 330, such that the measured portion of substrate is the center axis, and a second pyrometer can be disposed to intersect a second axis of substrate 330 that may be different than and/or parallel to the center axis. The optical paths of multiple pyrometers can be substantially parallel (e.g., plus or minus 20 degrees) to one another.

In response to having multiple temperature measurement devices measuring the temperature of a substrate at or near the same time (e.g., during the same temperature measuring event), the measured temperatures from the temperature measurement devices can form a temperature profile.

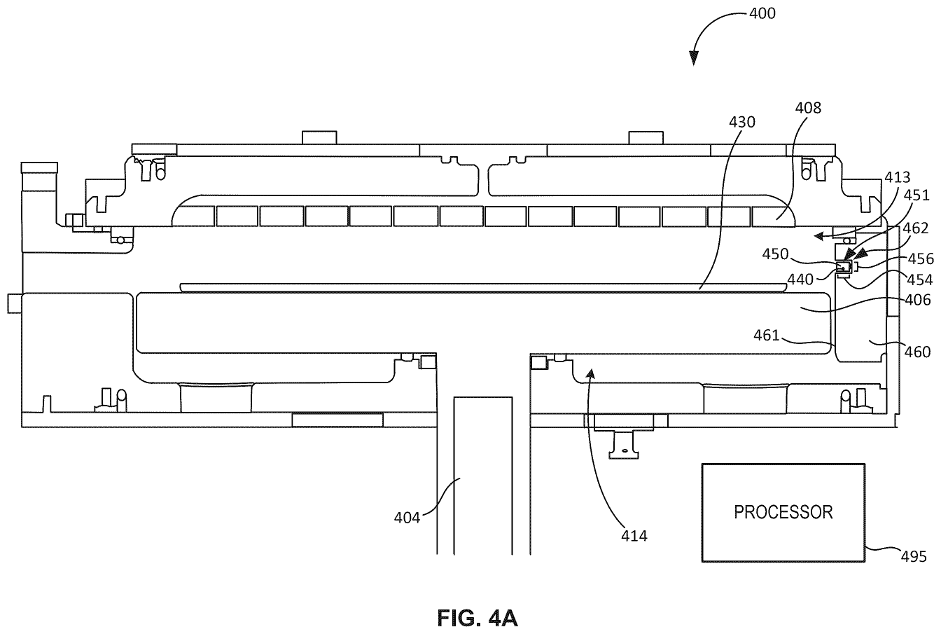

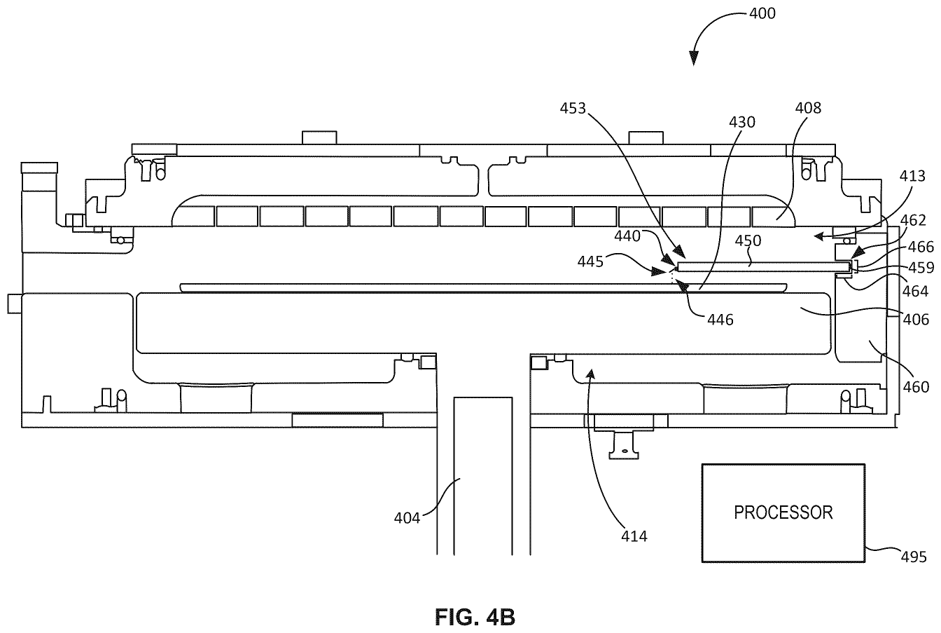

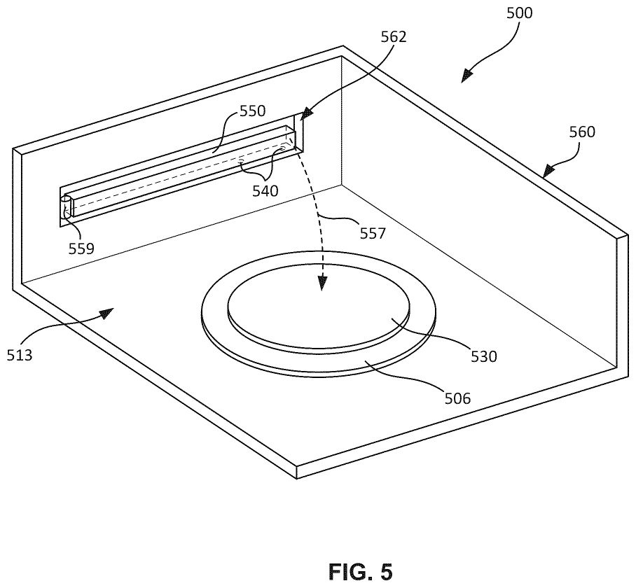

With reference to FIGS. 4A, 4B, and 5, in various examples, a reactor system can comprise a reaction chamber with a reaction space defined by a wall system. A substrate support (e.g., a susceptor) can be comprised in the reaction chamber configured to support a substrate thereon. The wall system can comprise a sidewall which can define at least a portion of the reaction space (e.g., the sidewall can serve as a side, top, bottom, or other boundary of the reaction space). A reactor system can comprise a translating arm coupled to the wall system. The translating arm can be configured to move/translate into the reaction space. At least a portion of the translating arm can be configured to travel proximate a portion of a substrate and/or proximate the portion of the substrate support configured to support a substrate, within the reaction chamber. For example, at least a portion of the translating arm can be configured to travel above and/or below the substrate and/or substrate support. The translating arm can comprise a temperature measurement device (or a component thereof) coupled to, or disposed in, the translating arm. The temperature measurement device (e.g., a pyrometer, or portion thereof) can move with the translating arm along a travel path, and can measure a temperature of a portion the substrate intersecting or overlapping at least a portion of the travel path.

As depicted in FIGS. 4A and 4B, reaction chamber 400 can comprise a reaction space 413 (an upper chamber) and a wall system defining at least a portion of reaction space 413. Wall system can comprise sidewall 460. A susceptor 406 can be disposed in reaction chamber 400, which may be able to move up or down via an elevator 404. Susceptor 406 can divide reaction chamber 400 into the upper chamber (reaction space 413) and a lower chamber 414. A substrate 430 can be disposed on susceptor 406 for processing within reaction chamber 400. One or more reaction fluids (e.g., gas) can be dispensed to reaction space 413 via showerhead 408.

Reaction chamber 400 can comprise a translating arm 450 coupled to the wall system (e.g., coupled to sidewall 460). Translating arm 450 can span between a proximal end and a distal end opposite the proximal end. The proximal ending of translating arm 450 can be coupled to sidewall 460. Translating arm 450 can move between a retracted position 451 and an extended position 453, for example, via a hinge 459 coupled to sidewall 460. Translating arm 450 can be coupled to sidewall 460 via hinge 459 (e.g., the proximal end of translating arm 450 can be coupled to hinge 459). A temperature measurement device 440 (e.g., a pyrometer and/or infrared camera or other thermal imagining device) can be coupled to translating arm 450. Temperature measurement device 440 can be coupled to translating arm 450 at any suitable position, for example, at or more proximate the distal end (than the proximal end) of translating arm 450. Temperature measurement device 440 can be disposed on translating arm 450 more proximate a substrate surface (e.g., the surface most proximate the substrate when the translating arm is in the extended position). As shown in FIGS. 4A and 4B, temperature measurement device 440 can be disposed on, adjacent, or proximate to a bottom surface of translating arm 450. Temperature measurement device 440 can be configured to travel with translating arm 450 during movement between retracted position 451 and extended position 453 along a travel path and measure a temperature of a portion of substrate 430 at least partially along the travel path (or at points along the travel path). The travel path can be arcuate or curved. In various examples, the translating arm can be coupled to the wall system and travel out into the reaction space, and over or below the substrate, in any suitable manner (e.g., extending linearly from the sidewall, traveling along a track disposed in the reaction chamber, and/or the like).

In various examples in which temperature measurement device 440 is a pyrometer, the pyrometer can comprise a pyrometer body and a fiber optic. The fiber optic can be coupled to translating arm 450. The pyrometer body can be disposed separate or external from translating arm 450, and/or external to reaction space 413. The fiber optic can be coupled to translating arm 450 so that its optical path for reading temperature is directed toward substrate 430. The fiber optic may have to be bent or curved in order to have an optical path directed toward substrate 430. In various examples, the fiber optic can be coupled to translating arm 450 so that the fiber optic is not directed toward substrate 430 (e.g., so the fiber optic is not bent curved or otherwise contorted). Therefore, translating arm 450 can comprise a mirror 445 coupled thereto and disposed (e.g., angled) such that the light and/or optical path 446 of the pyrometer fiber optic is reflected from mirror 445 toward substrate 430.

Translating arm 450 can be stored or disposed in retracted position 451 against and/or adjacent to a wall of the wall system (e.g., against chamber surface 461 of sidewall 460). In various examples, translating arm 450 can be stored or disposed in retracted position 451 at least partially inside of a wall of wall system. For example, translating arm 450 can be disposed within sidewall 460 in recess 462. Recess 462 can have a recess width 464 (e.g., the depth recess 462 spans past chamber surface 461 of sidewall 460, and into sidewall 460) that is complementary to an arm width 454 of translating arm 450. Recess 462 can have a recess height 466 that is complementary to an arm height 456 of translating arm 450. At least a portion of translating arm 450, or all of translating arm 450, can be disposed within sidewall 460 (within recess 462) when translating arm 450 is in the retracted position 451. When in retracted position 451, an exposed surface facing reaction space 413 of translating arm 450 can be substantially even or flush with chamber surface 461 of sidewall 460. Hinge 459 can be at least partially, or fully, disposed in recess 462.

Translating arm 450 can be disposed such that its travel path is above substrate 430 (e.g., such that translating arm 450 and/or recess 462 is in the upper chamber), and/or translating arm 450 can be disposed such that its travel path is below substrate 430 (e.g., such that translating arm 450 and/or recess 462 is in lower chamber 414).

With reference to FIG. 5, a reaction chamber 500 can comprise wall system 560 and/or a susceptor 506 configured to support a substrate 530. Reaction chamber 500 can comprise a translating arm 550 coupled to wall system 560. Translating arm 550 can be coupled to wall system 560 via a hinge 559, via which translating arm 550 can move (e.g., rotate about hinge 559) into the reaction space 513 of reaction chamber 500. When in the retracted position, translating arm can be disposed at least partially in recess 562. Translating arm 550 can move along a travel path 557. At least a portion of travel path 557 can be along and/or over (or below) substrate 530.

In various examples, a temperature measurement device can be coupled to the translating arm between the proximal and distal ends, and/or there can be more than one temperature measurement device coupled to the translating arm. For example, translating arm 550 can comprise temperature measurement devices 540. Temperature measurement devices 540 can be coupled to translating arm 550 at or proximate the distal end of translating arm 550 and/or in a middle position between the proximal and distal ends of translating arm 550. Temperature measurement devices 540 can be disposed at least partially within translating arm 550, and can be positioned such that an optical path of each temperature measurement device 540 can intersect and/or travel along substrate 530 in response to translating arm 550 traveling along at least a portion of travel path 557. The portion of substrate 530 along which an optical path of a temperature measurement device travels can be referred to as the measured portion of substrate 430. For example, a first temperature measurement device 540 (more proximate the distal end of translating arm 550) can measure the temperature of substrate 530 along a first measured portion, and a second temperature measurement device 540 (radially inward of the first temperature measurement device 540 proximate the distal end of translating arm 550) can measure the temperature of substrate 530 along a second measured portion. In various examples, a temperature measurement device can take a temperature measurement in response to the translating arm reaching the extended position, or any other position along the travel path.

In various examples, a temperature measurement device can be coupled to an existing reaction chamber component to measure the temperature of a substrate (e.g., after processing). Thus, temperature measurement devices can be retrofitted to existing reactor systems, and/or existing reactor systems may not require rearranging components in order to fit additional hardware associated with a temperature measurement device (e.g., a translating arm). For example, a temperature measurement device can be coupled to a substrate transfer device.

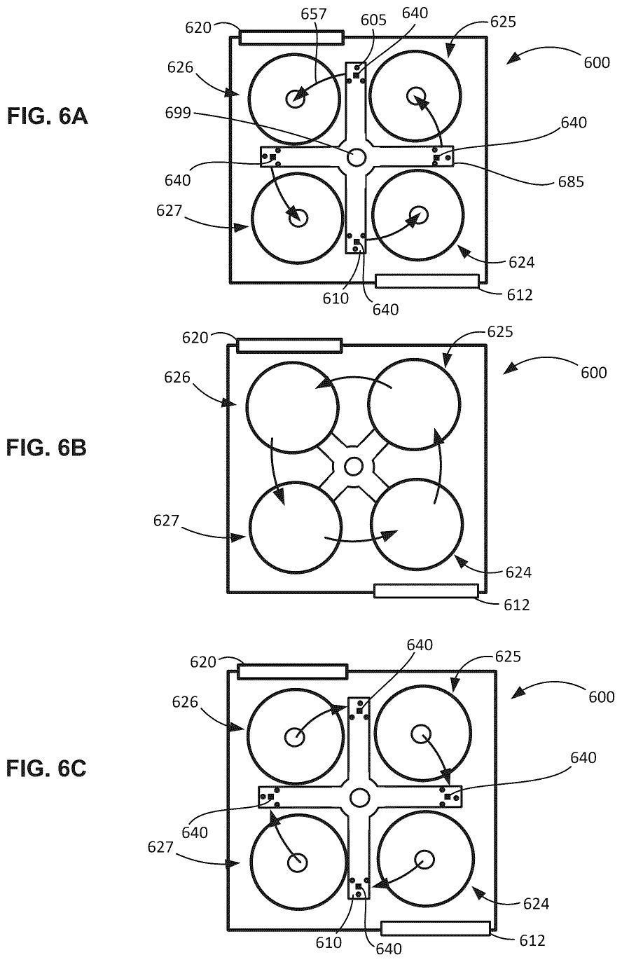

With reference to FIGS. 6A-6C, reactor system 600 can comprise multiple substrate stations (e.g., first station 624, second station 625, third station 626, and fourth station 627). Each substrate station can comprise a substrate support (e.g., a baseplate or susceptor). A substrate carrier 685 can be disposed between the substrate stations, such that the substrate support arms 610 of substrate carrier 685 can rotate about an axis and/or rotation point 699 between the substrate stations. Each substrate support arm can align with each of the substrate supports in the substrate stations. Thus, substrate carrier 685 can transfer substrates between substrate stations 624, 625, 626, and 627. For example, in FIG. 6A, substrate carrier 685 can be in a neutral position (e.g., in which none of the substrate support arms 610 are aligned with and/or contacting substrates in the substrate stations). To move the substrates in reactor system 600 to another substrate station, substrate carrier 685 can rotate 45 degrees from a neutral position to engage the respective substrate (e.g., on support pins 605) with the respective substrate support arm 610 (as shown in FIG. 6B), and then rotate 90, 180, or 270 degrees to advance the substrates to another substrate station.

As an example, a substrate can enter reactor system 600, for example, through a gate valve 612 into first station 624. Substrate carrier 685 can transfer the substrate from first station 624 to second station 625 (e.g., for preprocessing in which the substrate is cleaned, measured, or the like). Substrate carrier 685 can transfer the substrate from second station 625 to third station 626, from which the substrate can be transferred through gate valve 620 to a processing chamber for processing, and then return to third station 626 after processing. In response to substrate carrier 685 transferring substrates between substrate stations, substrate carrier 685 can remain in the same position with substrate support arms 610 aligned with the substrate stations, or substrate carrier 685 can rotate 45 degrees to return to a neutral position (e.g., rotate 45 degrees clockwise as in FIG. 6C after moving the substrates counterclockwise to another substrate station) until the next substrate transfer event.

A temperature measurement device 640 can be coupled to a substrate support arm 610 of substrate carrier 685. In various examples, a temperature measurement device 640 can be coupled to each substrate support arm 610 of substrate carrier 685. In response to a substrate support arm 610 of substrate carrier 685 receiving a substrate, the temperature measurement device 640 coupled to the respective substrate support arm 610 can measure the temperature of the received substrate. For example, in response to substrate carrier 685 remaining in the same position after transferring substrates, a substrate being further transferred to a processing chamber (with substrate support arms 610 remaining aligned with the substrate stations), and then receiving a processed substrate in third station 626, temperature measurement device 640 coupled to the respective substrate support arm 610 at third station 626 can measure the temperature of the processed substrate at a point intersecting the optical path of the respective temperature measurement device 640. As another example, in response to substrate carrier 685 returning to a neutral position after transferring substrates between substrate stations (e.g., as shown in FIG. 6A), and in response to receiving a substrate after processing (i.e., a processed substrate) in third station 626, substrate carrier 685 can rotate 45 degrees counterclockwise (or clockwise) to engage the processed substrate in third station 626. During such rotation, the optical path of the temperature measurement device 640 coupled to the respective substrate support arm 610 can move along travel path 657 aligned with the processed substrate. During such movement, temperature measurement device 640 can measure the temperature of the processed substrate along a portion thereof intersecting the optical path and the travel path. The portion of the processed substrate measured by temperature measurement device 640 (e.g., overlapping and/or aligned with the travel path of temperature measurement device 640) can be referred to as the measured portion of the processed substrate. In various examples, temperature measurement device 640 can be commanded or configured only to measure a substrate temperature in response to substrate carrier 685 rotating to engage a processed substrate (e.g., a substrate that has just exited a processing chamber). Thus, undesired temperature measurements or device usage can be avoided.

Temperature measurement device 640 can be any suitable device for measuring temperature (e.g., a pyrometer, thermal imaging device such as an infrared camera, and/or the like). Temperature measurement device 640 can be disposed such that an optical path thereof is directed toward a substrate (when the respective substrate support arm 610 is aligned with a substrate). In various examples in which temperature measurement device 640 is a pyrometer, the pyrometer can comprise a pyrometer body and a fiber optic. The fiber optic can be in electronic communication with the pyrometer body. The fiber optic can be coupled to the respective substrate support arm 610 of substrate carrier 685. The pyrometer body can be disposed separate from the respective substrate support arm 610 and/or substrate carrier 685, and/or external to reactor system 600.

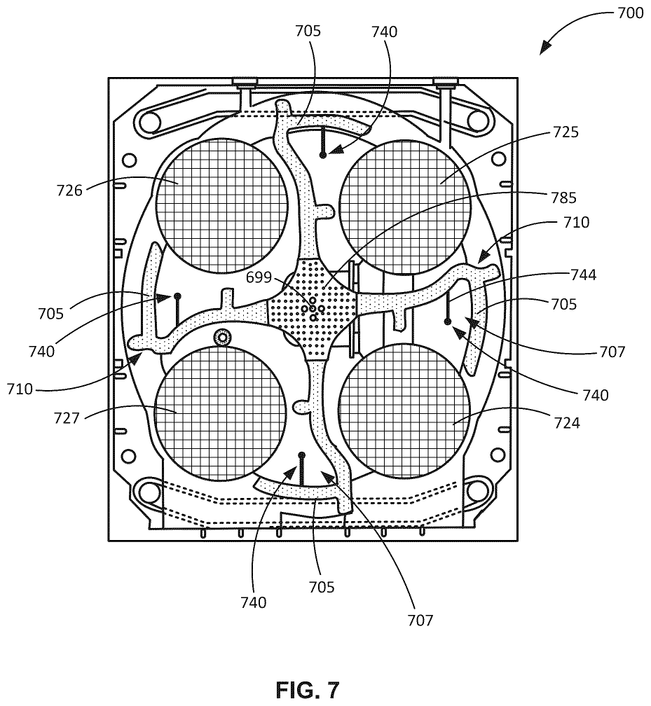

With reference to FIG. 7, a multi-armed substrate carrier 785 (an example of substrate carrier 685 in FIGS. 6A-6C) is depicted. Substrate carrier 785 can move/rotate and/or function similar to substrate carrier 685, that is, moving substrates between various substrate stations (e.g., between first station 724, second station 725, third station 726, and fourth station 727), each substrate station having a respective substrate support. Each substrate support arm 710 of substrate carrier 785 can comprise an end effector 705 configured to engage with a substrate (i.e., receive and/or support a substrate thereon), and transfer such substrate to another substrate station. A temperature measurement device 740 can be coupled to one or more end effectors 705. A temperature measurement device 740 can be coupled to each end effector 705.

End effectors 705 can comprise an angled or curved body at least partially defining an end effector void 707 of the respective end effector. An end effector 705 can be L-shaped, hook shaped, and/or the like. In response to a respective substrate being disposed on an end effector 705, the end effector angled body can engage with a peripheral portion of the respective substrate and end effector void 707 can be aligned with at least a portion of a center portion of the respective substrate. Temperature measurement device 740 coupled to an end effector 705 can be coupled such that the temperature measurement device 740 is disposed in and/or aligned with the respective end effector void 707. Temperature measurement device 740 can be coupled to an end effector 705 via a device support 744, which extends from the body of the end effector 705 into the end effector void 707. Such a position can allow greater intersection between a travel path and/or optical path of temperature measurement device 740, and the respective substrate, thus allowing a greater possible measured portion of the substrate. Such a position of a temperature measurement device 740 can further allow temperature measurement within a center portion of the substrate, rather than on a periphery of the substrate.

In response to a substrate support arm 710 of substrate carrier 785 receiving a substrate, the temperature measurement device 740 coupled to the respective substrate support arm 710 can measure the temperature of the received substrate. For example, in response to substrate carrier 785 remaining in the same position after transferring substrates, a substrate being further transferred to a processing chamber (with substrate support arms 710 remaining aligned with the substrate stations), and then receiving a processed substrate, temperature measurement device 740 coupled to the respective substrate support arm 710 can measure the temperature of the substrate at a point intersecting the optical path of the respective temperature measurement device 740. As another example, in response to substrate carrier 785 returning to a neutral position after transferring substrates between substrate stations (e.g., the position shown in FIG. 6A), and in response to receiving a substrate after processing (i.e., a processed substrate), substrate carrier 785 can rotate 45 degrees counterclockwise (or clockwise) to engage the processed substrate. During such rotation, the optical path of the temperature measurement device 740 coupled to the respective substrate support arm 710 can move along its travel path aligned with the processed substrate. During such movement, temperature measurement device 740 can measure the temperature of the processed substrate along at least a portion thereof intersecting the optical path and the travel path. The portion of the processed substrate measured by temperature measurement device 740 (e.g., overlapping and/or aligned with the travel path of temperature measurement device 740) can be referred to as the measured portion of the processed substrate. In various examples, temperature measurement device 740 can be commanded only to measure a substrate temperature in response to substrate carrier 785 rotating to engage a processed substrate (e.g., a substrate that has just exited a processing chamber). Thus, undesired temperature measurements or device usage can be avoided.

Temperature measurement device 740 can be any suitable device for measuring temperature (e.g., a pyrometer, thermal imaging device such as an infrared camera, and/or the like). Temperature measurement device 740 can be disposed such that an optical path thereof is directed toward a substrate (when the respective substrate support arm 710 is aligned with a substrate). In various examples in which temperature measurement device 740 is a pyrometer, the pyrometer can comprise a pyrometer body and a fiber optic. The fiber optic can be in electronic communication with the pyrometer body. The fiber optic can be coupled to the respective substrate support arm 710 of substrate carrier 785. The pyrometer body can be disposed separate from the respective substrate support arm 710 and/or substrate carrier 785, and/or external to reactor system 700.

In various examples, the systems discussed herein can comprise a processor. The processor can be electrically connected to a temperature measurement device in a reactor system, as discussed herein, and configured to receive temperature measurements of the substrate from the temperature measurement device. For example, in reactor system 300, processor 395 can be electrically connected to temperature measurement device 340 via an electrical connection 334. As another example, in FIGS. 4A and 4B, temperature measurement device 440 can be in electronic communication with processor 495. Likewise, temperature measurement device 540, 640, and/or 740 can be electronically coupled to, or in communication with, a processor. Temperature measurements obtained by a temperature measurement device, as discussed herein, can be transmitted to a respective processor for storage, processing, presentation, and/or the like. The system and/or processor(s) can also comprise a tangible, non-transitory memory configured to communicate with the processor. The tangible, non-transitory memory can have instructions stored thereon that, in response to execution by the processor, cause the processor to perform operations.

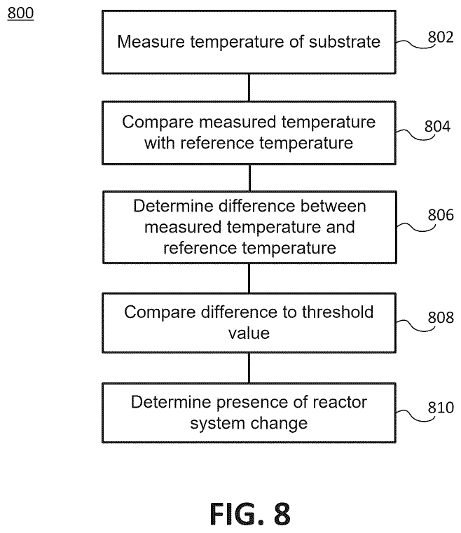

With additional reference to FIG. 8, a method 800 for detecting a system change is depicted. The temperature of a substrate can be measured (step 802). The substrate temperature can be measured after a substrate is processed (i.e., a processed substrate). As discussed herein, a reactor system can comprise a temperature measurement device which extends an optical path that can overlap or intersect a portion of a substrate. For example, temperature measurement devices 240/340 in systems 200/300 comprise optical paths (e.g., optical path 346) that intercept a substrate as the substrate travels between chambers in a reactor system, and can measure the temperatures of the substrate portions that overlap with the optical paths of the temperature measurement devices. As another example, temperature measurement devices 440/540 in systems 400/500 move with a translating arm over or around a substrate, and can measure a temperature of the substrate portions that overlap with the optical paths of the temperature measurement devices and the travel paths thereof (e.g., temperature measurements can be obtained during translation of the translating arm and/or temperature measurement device, and/or in response to the translating arm and/or temperature measurement device reaching a certain position, e.g., an extended position). As another example, temperature measurement devices 640/740 in systems 600/700 move with a substrate carrier to engage a substrate, and can measure a temperature of the substrate portions that overlap with the optical paths of the temperature measurement devices and the travel paths thereof (e.g., temperature measurements can be obtained during movement/rotation of the substrate carrier under a substrate).

In various examples in which multiple temperature measurement devices measure the temperature of a substrate at or near the same time (e.g., during the same temperature measuring event), the measured temperatures from the temperature measurement devices can form and be comprised in a temperature profile.

The processor can compare the measured temperature value with a reference temperature value (step 804). The temperature value can be a temperature profile, in various examples. In such examples, the reference temperature value can be a reference temperature profile. The reference temperature value can be a substrate temperature that indicates that the reactor system and the processing method is functioning and/or progressing correctly or otherwise as desired. That is, the reference temperature can be the substrate temperature post-processing achieved in response to the respective system functioning properly.

In response to comparing the measured temperature value with a reference temperature value, a difference therebetween can be determined (e.g., by the processor) (step 806). If there is no difference (e.g., a temperature difference), the processor can determine that the system is operating properly, and no further action may be needed. In response to a difference being detected, the difference can be compared to a threshold value (e.g., by the processor) (step 808). (The threshold value can be a threshold profile value in examples including multiple temperature measurement devices and multiple measured temperatures making up a temperature profile.). The threshold value can be a value (e.g., an absolute value) above or below which, or a range outside of which, an error or malfunction can be detected (i.e., the threshold value can be an acceptable error level). That is, if the temperature difference is greater than the threshold value (or outside an acceptable threshold value range), such a difference can indicate a malfunction of the reactor system or processing method. Accordingly, based on the comparison between the temperature difference and the threshold value, a change in the reactor system can be determined (e.g., by the processor) (step 810). If the difference is within the acceptable range of difference (e.g., within an acceptable error margin), or for example below a maximum threshold value, then the processor can determine that the system and/or process is functioning properly, and no further action may be taken. If the difference is, for example, greater than the threshold value (or outside the acceptable threshold value range), the processor can detect an error or malfunction with the system or process. In response, evaluation of the system can be conducted, and any needed adjustments can take place.

The systems and methods herein allow for early detection and/or addressing of errors within a system, such that a malfunctioning system is not utilized for an extended period. That is, if a system is malfunctioning, it would be undesirable to continue to utilize the system to produces films on substrates (e.g., for semiconductors), as the produced films and substrates may not meet acceptable specifications. Thus, by measuring the temperature of substrates via the systems and methods disclosed herein (e.g., measuring temperatures of processed substrates within the system before the substrates are delivered from the system and/or directly after or temporally soon after a substrate's processing), errors and/or malfunctions can be detected early (or immediately) and/or addressed before such an error propagates to other substrates, resulting in further products failing to meet desired specifications.

The components of the various systems herein can be implemented in any suitable combination or arrangement (e.g., within one or more reactor systems). For example, a reactor system can comprise one or more of the temperature measurement devices depicted in FIGS. 2 and 3, FIGS. 4A-4B and 5 (including a translating arm), and/or FIGS. 6A-6C and 7 (including a temperature measurement device coupled to a substrate carrier).

The example embodiments of the disclosure described above do not limit the scope of the disclosure, since these embodiments are merely examples of the embodiments of the disclosure, which is defined by the appended claims and their legal equivalents. Any equivalent embodiments are intended to be within the scope of this disclosure. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A reactor system, comprising:
a plurality of substrate supports;
a substrate carrier comprising a plurality of substrate support arms, wherein the substrate carrier is configured to rotate about an axis such that each of the plurality of substrate support arms is able to align with each of the plurality of substrate supports, and wherein the substrate carrier is configured to move substrates between the plurality of substrate supports; and
a temperature measurement device coupled to at least one of the plurality of substrate support arms, wherein the temperature measurement device is configured to measure a temperature of a measured portion of a processed substrate and travels with the at least one of the plurality of substrate support arms during rotation along a travel path, wherein the measured portion of the processed substrate, disposed on one of the plurality of substrate supports, overlaps the travel path.

2. The reactor system of claim 1, wherein each of the plurality of substrate support arms comprises an end effector configured to engage a respective substrate, wherein the temperature measurement device is coupled to the end effector of each of the plurality of substrate support arms.

3. The reactor system of claim 2, wherein the end effector comprises an angled body at least partially defining an end effector void of the end effector, such that in response to a respective substrate being disposed on the end effector, the angled body engages with a peripheral portion of the respective substrate and the end effector void is aligned with at least a portion of a center portion of the respective substrate.

4. The reactor system of claim 3, wherein the temperature measurement device is positioned in or aligned with the end effector void.

5. The reactor system of claim 1, wherein the temperature measurement device is at least one of a pyrometer or infrared camera.

6. The reactor system of claim 1, further comprising:
a processor operably coupled to the temperature measurement device; and
a tangible, non-transitory memory configured to communicate with the processor, the tangible, non-transitory memory having instructions stored thereon that, in response to execution by the processor, cause the processor to perform operations comprising:
measuring, by the processor and the temperature measurement device, and as the substrate carrier rotates, the temperature along the measured portion of processed substrate that overlaps the travel path of the temperature measurement device; and
comparing, by the processor, the measured temperature with a reference temperature.

7. The reactor system of claim 6, wherein the operations further comprise:
determining, by the processor, a difference between the measured temperature and the reference temperature; and
comparing, by the processor, the difference to a threshold value.

8. A reactor system, comprising:
a reaction chamber comprising a wall system defining a reaction space;
a substrate support disposed in the reaction chamber and configured to receive a substrate thereon;
a translating arm coupled to the wall system in the reaction chamber, wherein the translating arm is configured to move within the reaction space, and at least a portion of the translating arm is configured to travel above or below a substrate disposed on the substrate support; and
a temperature measurement device coupled to the translating arm, wherein the temperature measurement device is configured to move with the translating arm and travel above or below the substrate along a travel path and measure a temperature of a measured portion of the substrate overlapping the travel path.

9. The reactor system of claim 8, wherein the translating arm is coupled to a sidewall of the wall system, and wherein the translating arm rotates via a hinge between a retracted position and an extended position, wherein the travel path is curved.

10. The reactor system of claim 9, wherein the sidewall comprises a recess in which the hinge is at least partially disposed and in which the translating arm is at least partially housed when in the retracted position.

11. The reactor system of claim 10, wherein the reaction chamber comprises an upper chamber and a lower chamber, wherein the recess in the sidewall is comprised in the lower chamber.

12. The reactor system of claim 8, wherein the temperature measurement device is at least one of a pyrometer or infrared camera.

13. The reactor system of claim 8, wherein the temperature measurement device is a pyrometer comprising a pyrometer body and a fiber optic, wherein the pyrometer body is disposed external to the reaction chamber and the fiber optic is coupled to the translating arm within the reaction chamber.

14. The reactor system of claim 13, further comprising a mirror coupled to the translating arm, wherein the mirror is angled to direct an optical path from the fiber optic toward the substrate.

15. The reactor system of claim 8, further comprising:
a processor operably coupled to the temperature measurement device; and
a tangible, non-transitory memory configured to communicate with the processor, the tangible, non-transitory memory having instructions stored thereon that, in response to execution by the processor, cause the processor to perform operations comprising:
measuring, by the processor and the temperature measurement device, and as the translating arm moves, the temperature along the measured portion of the substrate; and
comparing, by the processor, the measured temperature with a reference temperature.

16. The reactor system of claim 15, wherein the operations further comprise:
determining, by the processor, a difference between the measured temperature and the reference temperature; and
comparing, by the processor, the difference to a threshold value.

17. A reactor system, comprising:
a first chamber;
a load lock chamber coupled to the first chamber, wherein a substrate travels through the load lock chamber along a transfer path in moving to and from the first chamber;
a first pyrometer comprising a first pyrometer body and a first fiber optic, wherein the first pyrometer body is disposed external to the load lock chamber and the first fiber optic is disposed through an upper wall of, and into, the load lock chamber, wherein a first optical path of the first pyrometer intersects the transfer path of the substrate;
a processor operably coupled to the first pyrometer; and
a tangible, non-transitory memory configured to communicate with the processor, the tangible, non-transitory memory having instructions stored thereon that, in response to execution by the processor, cause the processor to perform operations comprising:
measuring, by the processor and the first pyrometer, and as the substrate moves along the transfer path, a first temperature along a first measured portion of the substrate that intersects the first optical path of the first pyrometer; and
comparing, by the processor, the first temperature with a reference temperature.

18. The reactor system of claim 17, wherein the operations further comprise:
determining, by the processor, a difference between the first temperature and the reference temperature; and
comparing, by the processor, the difference to a threshold value.

19. The reactor system of claim 18, further comprising a second pyrometer comprising a second pyrometer body and a second fiber optic, wherein the second pyrometer body is disposed external to the load lock chamber and the second fiber optic is disposed through the upper wall of, and into, the load lock chamber, wherein a second optical path of the second pyrometer is parallel to the first optical path of the first pyrometer and intersects the transfer path of the substrate.

20. The reactor system of claim 19, wherein the operations further comprise:
measuring, by the processor and the second pyrometer, and as the substrate moves along the transfer path, a second temperature along a second measured portion of the substrate that intersects the second optical path of the second pyrometer,
wherein the first temperature and the second temperature are comprised in a temperature profile;
comparing, by the processor, the temperature profile with a reference temperature profile;
determining, by the processor, a difference between the temperature profile and the reference temperature profile; and
comparing, by the processor, the difference to a threshold profile value.
